(19) United States
(12) Patent Application Publication
(10) Pub. No.: US 2026/0362834 A1
(43) Pub. Date: Nov. 12, 2026

(54) IMAGE SENSING DEVICE

(71) Applicant: VisEra Technologies Company Limited, Hsin-Chu City (TW)

(72) Inventors: Chun-Yuan WANG, Hsin-Chu City (TW); Po-Hsiang WANG, Hsin-Chu City (TW); Han-Lin WU, Hsin-Chu City (TW)

(21) Appl. No.: 19/205,252

(22) Filed: May 12, 2025

(51) Int. Cl. H10F 39/00

(52) U.S. Cl. CPC H10F 39/8053; H10F 39/806

(57) ABSTRACT

An image sensing device is provided. The image sensing device includes a sensor substrate having a normal direction. The image sensing device includes a color filter layer over the sensor substrate and a first optical layer formed over the color filter layer. The image sensing device also includes a second optical layer formed over the first optical layer. The second optical layer includes an optical ring structure having an inner edge and an outer edge around a central axis of the optical ring structure. The central axis is substantially parallel to the normal direction. The second optical layer includes a plurality of optical poles. When viewed in the central axis of the optical ring structure, the optical poles are located around the outer edge of the optical ring structure, and the radius of the optical poles is less than the inner radius of the optical ring structure.

### BACKGROUND

### Field of the Disclosure

The present disclosure relates to an image sensing device, and in particular it relates to an image sensing device including a plurality of optical poles around the outer edge of the optical ring structure over the sensor substrate.

### Description of the Related Art

Existing image sensing devices receive incident light so as to detect and convey information used to form an image. However, the performance of auto-focus in current image sensing devices still needs to be improved. Therefore, finding a way to solve the above problem has become an important issue.

### BRIEF SUMMARY

Some embodiments of the disclosure provide an image sensing device, including sensor substrate and a color filter layer over the sensor substrate. The image sensing device includes a first optical layer formed over the color filter layer. The image sensing device also includes a second optical layer formed over the first optical layer. The second optical layer includes an optical ring structure and a plurality of optical poles located around the outer edge of the optical ring structure.

For making the features and advantages (as described above) of the present disclosure more clear, or for other purposes, some embodiments are provided in the following paragraphs, and a subsequent detailed description is provided below with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1 is a schematic plan view illustrating an image sensing device in accordance with some embodiments of the present disclosure;

FIG. 2 is a schematic cross-sectional view illustrating the image sensing device along the line A-A′ shown in FIG. 1 in accordance with some embodiments of the present disclosure;

FIG. 3 is a schematic plan view illustrating the image sensing device in accordance with some embodiments of the present disclosure;

FIG. 4 is a schematic plan view illustrating the image sensing device in accordance with some embodiments of the present disclosure;

FIG. 5 is a schematic plan view illustrating the image sensing device in accordance with some embodiments of the present disclosure;

FIG. 6 is a schematic plan view illustrating the image sensing device in accordance with some embodiments of the present disclosure;

FIG. 7 is a schematic plan view illustrating the image sensing device in accordance with some embodiments of the present disclosure;

FIG. 8 is a schematic plan view illustrating the image sensing device in accordance with some embodiments of the present disclosure;

FIG. 9 is a schematic plan view illustrating the image sensing device in accordance with some embodiments of the present disclosure;

FIG. 10 is a schematic plan view illustrating the image sensing device in accordance with some embodiments of the present disclosure;

FIG. 11 is a schematic plan view illustrating the image sensing device in accordance with some embodiments of the present disclosure;

FIG. 12 is a schematic plan view illustrating the image sensing device in accordance with some embodiments of the present disclosure;

FIG. 13 is a schematic plan view illustrating the image sensing device in accordance with some embodiments of the present disclosure;

FIG. 14 is a schematic plan view illustrating the image sensing device in accordance with some embodiments of the present disclosure;

FIG. 15 is a schematic plan view illustrating the image sensing device in accordance with some embodiments of the present disclosure;

FIG. 16 is a schematic plan view illustrating the image sensing device in accordance with some embodiments of the present disclosure;

FIG. 17 is a schematic plan view illustrating the image sensing device in accordance with some embodiments of the present disclosure; and

FIG. 18 is a schematic plan view illustrating the image sensing device in accordance with some embodiments of the present disclosure.

### DETAILED DESCRIPTION

The image sensing devices of some embodiments of the present disclosure are described in the following description. The specific embodiments disclosed are provided merely to clearly describe the usage of the present disclosure by some specific methods without limiting the scope of the present disclosure.

In addition, in this specification, relative expressions may be used. For example, “lower”, “bottom”, “higher” or “top” are used to describe the position of one element relative to another. It should be noted that if a device is flipped upside down, an element that is “lower” will become an element that is “higher.”

It should be understood that, although the terms “first”, “second,” etc. may be used herein to describe various elements, regions, layers and/or portions, and these elements, regions, layers, and/or portions should not be limited by these terms. These terms are only used to distinguish one element, component, region, layer, or portion. Thus, a first element, component, region, layer or portion discussed below could be termed a second element, component, region, layer or portion without departing from the teachings of some embodiments of the present disclosure.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure.

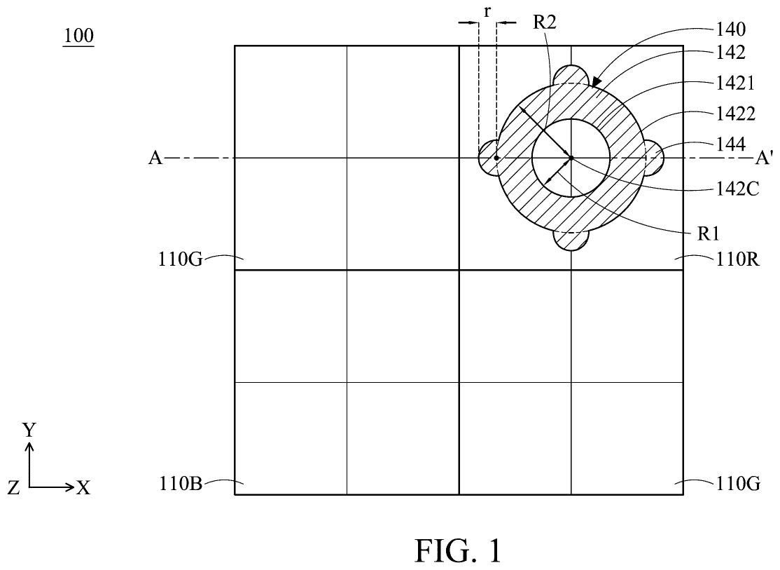

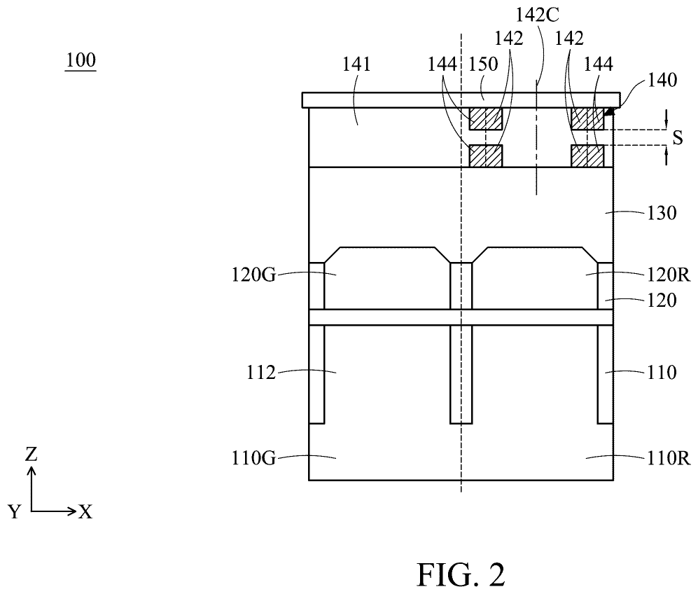

FIG. 1 is a schematic plan view illustrating an image sensing device 100 in accordance with some embodiments of the present disclosure. FIG. 2 is a schematic cross-sectional view illustrating the image sensing device 100 along the line A-A′ shown in FIG. 1 in accordance with some embodiments of the present disclosure. As shown in FIGS. 1 and 2, an image sensing device 100 is provided and includes a sensor substrate 110, a color filter layer 120, a first optical layer 130, a second optical layer 140, and an anti-reflection layer 150. In some embodiments, the sensor substrate 110 includes a plurality of sensors 112, and defines a plurality of pixels (including a red pixel 110R, a green pixel 110G, and a blue pixel 110B, referring to FIG. 1, for example). These pixels may constitute a basic unit of Bayer patterns, and the following embodiments are discussed based on these pixels. The color filter layer 120 is formed over the sensor substrate 110, and includes a plurality of color filters (including a red color filter 120R, a green color filter 120G, and a blue color filter, which is not individually illustrated). For ease of understanding, the pixels may be defined as a region that one sensor 112 and the overlying color filter occupy. That is, the red color filter 120R is disposed over the sensor 112 in the red pixel 110R. Similarly, the green color filter 120G is disposed over the sensor 112 in the green pixel 110G. The boundary (shown as the dotted line in FIGS. 1 and 2) between adjacent pixels may be defined at the middle point of the outer edges of the adjacent sensors 112. However, the pixels may be defined as any region that can be realized by those skilled in the art.

Furthermore, the first optical layer 130 is formed over the color filter layer 120, and the second optical layer 140 is formed over the first optical layer 130. In some embodiments, an interface between the first optical layer 130 and the color filter layer 120 is not completely flat, since the top surface of the red color filter 120R and/or the green color filter 120G may not be coplanar with a horizontal plane (such as the X-Y plane). However, the present disclosure is not limited thereto. In some embodiments, the first optical layer 130 is made of transparent dielectric material so that the sensors 112 may receive the incident light. For example, the refractive index of the first optical layer 130 is in a range from about 1.1 to about 1.6, such as about 1.2, but the present disclosure is not limited thereto.

In some embodiments, the second optical layer 140 is formed over the first optical layer 130. Similarly, the second optical layer 140 includes an optical medium 141, which is made of transparent dielectric material so that the sensors 112 may receive the incident light. In some embodiments, the refractive index of the optical medium 141 is in a range from about 1.1 to about 1.6, but the present disclosure is not limited thereto. In some embodiments, the material of the first optical layer 130 is different from the material of the optical medium 141, but the present disclosure is not limited thereto.

In some embodiments, the second optical layer 140 includes an optical ring structure 142 and a plurality of optical poles 144 (referring to FIGS. 1 and 2, for example) located around the outer edge of the optical ring structure 142. The optical ring structure 142 and the optical poles 144 are surrounded by the optical medium 141. In some embodiments, the refractive index of the optical ring structure 142 and the optical poles 144 is in a range from about 1.7 to about 2.3, but the present disclosure is not limited thereto. As set forth above, the refractive index of the first optical layer 130 (and the optical medium 141) is different from the refractive index of the optical ring structure 142 and the optical poles 144. In some embodiments, the refractive index of the first optical layer 130 (and the optical medium 141) is less than the refractive index of the optical ring structure 142 and the optical poles 144. The incident light passes through the optical ring structure 142 and the optical poles 144, and light-coupling effect occurs. As a result, the optical ring structure 142 and the surrounding optical poles 144 may reduce the size of the light spot, thereby improving the performance of auto-focus of the image sensing device 100.

In some embodiments, the optical ring structure 142 is substantially parallel to the horizontal plane (such as the X-Y plane). As shown in FIG. 2, two layers of the optical ring structure 142 are illustrated. However, it should be noted that more or less layers of the optical ring structure 142 may be formed in the second optical layer 140, and these configurations are all included within the scope of the present disclosure. In some embodiments, the spacing S between adjacent layers of the optical ring structures 142 is from about 10 nm to about 200 nm. Of course, the optical ring structure 142 and the optical poles 144 shown in each figure of the present disclosure can be adopted in the image sensing device 100. In some embodiments, the layers of the optical ring structures 142 include different patterns. That is, the optical ring structures 142 may be any embodiment shown in the present disclosure. Furthermore, the anti-reflection layer 150 is formed on the second optical layer 140. The anti-reflection layer 150 is configured to reduce the reflection of the incident light and increase the light transmittance. As such, the sensibility of the sensor in the image sensing device 100 may be enhanced.

Referring back to FIG. 1, it should be noted that FIG. 1 illustrates a basic unit of the Bayer patterns, including one red pixel 110R, two green pixel 110G, and one blue pixel 110B. and the image sensing device 100 may include any number of these pixels. Furthermore, for the sake of clarity, only the upper optical ring structure 142 shown in FIG. 2 is illustrated. As shown in FIG. 1, the optical ring structure 142 is circular when viewed in the central axis 142C (for example, the Z axis) of the optical ring structure 142. The optical ring structure 142 has an inner edge 1421 and an outer edge 1422. In some embodiments, the optical ring structure 142 has an inner radius R1 measured from the central axis 142C of the optical ring structure 142 to the inner edge 1421 in a direction perpendicular to the central axis of the optical ring structure. The optical ring structure 142 further has an outer radius R2 measured from the central axis 142C of the optical ring structure 142 to the outer edge 1422. The outer radius R2 is greater than the inner radius R1. For example, the inner radius R1 is in a range from about 25 nm to about 350 nm, and the outer radius R2 is in a range from about 100 nm to about 1000 nm.

In addition, the optical poles 144 (for example, four) are disposed around the outer edge 1422 of the optical ring structure 142. In the present embodiment, the optical poles 144 are integrated with the outer edge 1422 of the optical ring structure 142. That is, the optical poles 144 extends from and in direct contact with the outer edge 1422. In other words, the periphery of one of the optical poles 144 is an arc connected to the outer edge 1422 of the optical ring structure 142. Because these optical poles 144 are partial circles when viewed in the central axis 142C (for example, the Z axis) of the optical ring structure 142, they may also be referred to as “the ear structures 144” in some embodiments. The optical ring structure 142 and the optical poles 144 are made of a dielectric material. The radius r of the optical poles 144 is less than the inner radius R1 of the optical ring structure 142. Accordingly, the light-coupling effect occurs, and the size of the light spot can be reduced, thereby improving the performance of auto-focus of the image sensing device 100. It should be noted that although four optical poles 144 are shown in the present embodiment, more or less optical poles 144 can be disposed, and all of these configurations are included within the present disclosure. In some embodiments, the optical poles 144 are arranged around the outer edge 1422 of the optical ring structure 142 at a constant interval. In particular, the optical poles 144 may be located on the X axis and the Y axis, and an angle of 90 degrees is formed between adjacent optical poles 144. As a result, the light-coupling effect of the incident light would be uniform across the image sensing device 100, thereby improving the performance of the image sensing device 100.

In some embodiments, the central axis 142C of the optical ring structure 142 may be aligned with the center of the red pixel 110R (i.e., the center of the sensor 112 in the red pixel 110R). However, the present disclosure is not limited thereto. It should be noted that the optical ring structure 142 and the optical poles 144 are located directly over (i.e., overlaps) the red pixel 110R in the present embodiment. However, in some other embodiments, the optical ring structure 142 and the optical poles 144 may also be located directly over the green pixel 110G and/or the blue pixel 110B, and any possible configuration of the optical ring structure 142 and the optical poles 144 is included within the scope of the present disclosure.

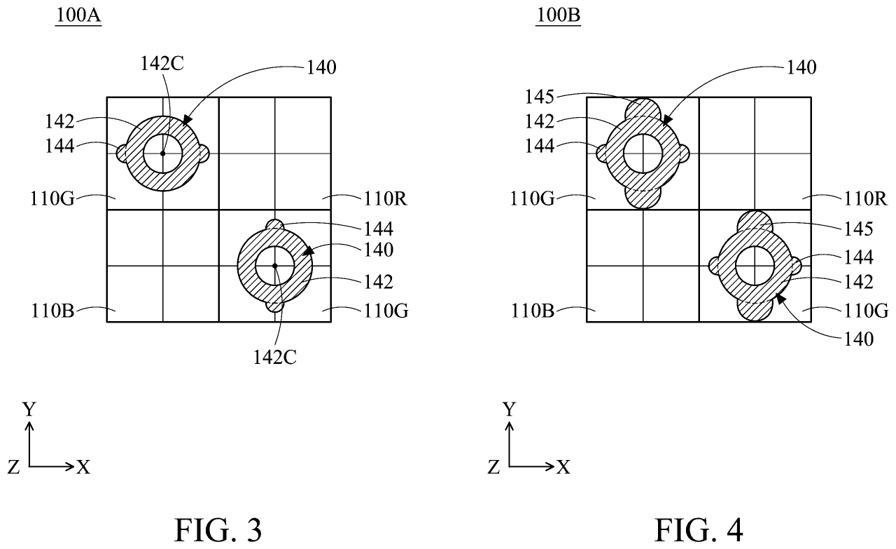

FIG. 3 is a schematic plan view illustrating the image sensing device 100A in accordance with some embodiments of the present disclosure. It is noted that the image sensing device 100A in the present embodiment may include the same or similar elements, portions or layers as the image sensing device 100 shown in FIG. 1. Those elements, portions or layers are labeled as the same or similar numerals, and will not be discussed in detail again. The difference between the present embodiment and the embodiment shown in FIG. 1 is that as shown in FIG. 3, the optical ring structures 142 are located directly over the green pixels 110G, and two optical poles 144 are disposed around each optical ring structure 142. In particular, the optical poles 144 may be arranged along the X axis or the Y axis, and the optical poles 144 around the same optical ring structure 142 may be opposite to each other. That is, the optical ring structures 142 may be symmetrical around the central axis 142C of the optical ring structures 142 (i.e., the center of the green pixels 110G).

FIG. 4 is a schematic plan view illustrating the image sensing device 100B in accordance with some embodiments of the present disclosure. It is noted that the image sensing device 100B in the present embodiment may include the same or similar elements, portions or layers as the image sensing device 100A shown in FIG. 3. Those elements, portions or layers are labeled as the same or similar numerals, and will not be discussed in detail again. The difference between the present embodiment and the embodiment shown in FIG. 3 is that as shown in FIG. 4, the second optical layer 140 includes two optical poles 144 and two optical poles 145 which have different sizes (such as, radius, perimeter, etc.) when viewed in the central axis 142C (for example, the Z axis) of the optical ring structure 142. That is, four optical poles are provided around the optical ring structure 142. In particular, the size (such as the surface area) of the optical poles 145 is greater than the size (such as the surface area) of the optical poles 144. In some embodiments, the optical poles 145 may be arranged along the Y axis, and the optical poles 144 may be arranged along the X axis. However, the present disclosure is not limited thereto. In some other embodiments, the optical poles 145 may be arranged along the X axis, and the optical poles 144 may be arranged along the Y axis.

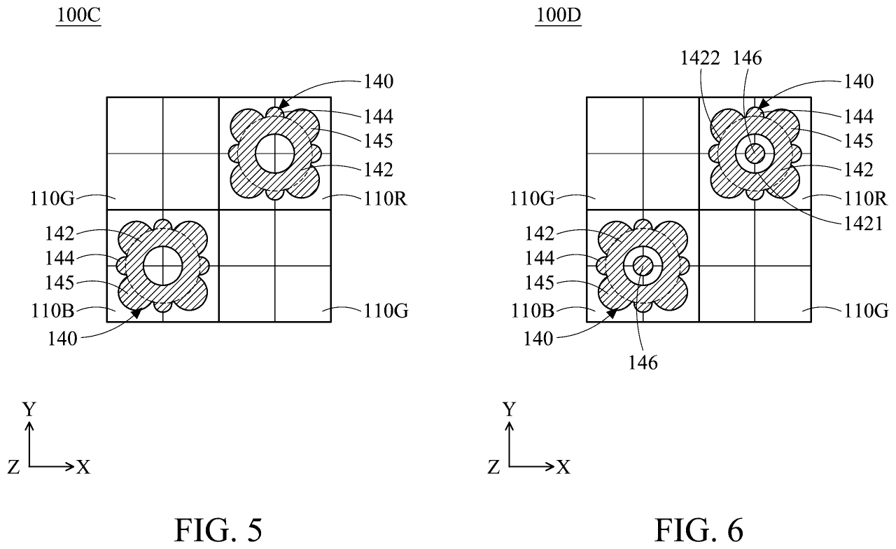

FIG. 5 is a schematic plan view illustrating the image sensing device 100C in accordance with some embodiments of the present disclosure. It is noted that the image sensing device 100C in the present embodiment may include the same or similar elements, portions or layers as the image sensing device 100B shown in FIG. 4. Those elements, portions or layers are labeled as the same or similar numerals, and will not be discussed in detail again. The difference between the present embodiment and the embodiment shown in FIG. 4 is that as shown in FIG. 5, the second optical layer 140 includes four optical poles 144 and four optical poles 145 which have different sizes when viewed in the central axis 142C (for example, the Z axis) of the optical ring structure 142. That is, eight optical poles are provided around the optical ring structure 142. In particular, the optical poles 145 may be arranged along the diagonal direction of the red pixel 110R and the blue pixel 110B, and the optical poles 144 may be arranged along the X axis and the Y axis. As a result, the light-coupling effect can be improved at corners of the pixels, thereby improving the performance of the image sensing device 100C.

FIG. 6 is a schematic plan view illustrating the image sensing device 100D in accordance with some embodiments of the present disclosure. It is noted that the image sensing device 100D in the present embodiment may include the same or similar elements, portions or layers as the image sensing device 100C shown in FIG. 5. Those elements, portions or layers are labeled as the same or similar numerals, and will not be discussed in detail again. The difference between the present embodiment and the embodiment shown in FIG. 5 is that as shown in FIG. 6, the second optical layer 140 further includes an inner optical pillar 146 located inside the inner edge 1421 of the optical ring structure 142. In particular, the inner optical pillar 146 may be aligned with the center of the optical ring structure 142. For example, the distance between the edge of the inner optical pillar 146 and the inner edge 1421 of the optical ring structure 142 is constant. As a result, the light-coupling effect can be improved at the center of the pixels, thereby improving the performance of the image sensing device 100D.

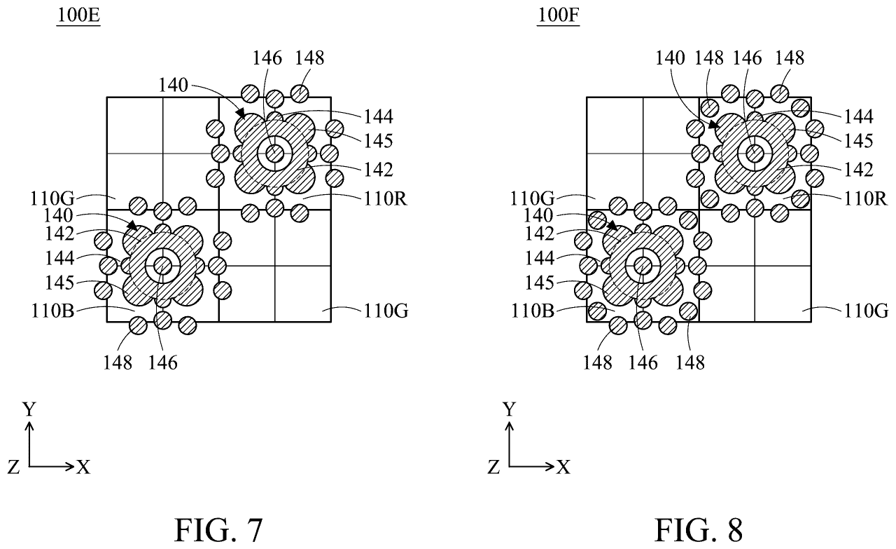

FIG. 7 is a schematic plan view illustrating the image sensing device 100E in accordance with some embodiments of the present disclosure. It is noted that the image sensing device 100E in the present embodiment may include the same or similar elements, portions or layers as the image sensing device 100D shown in FIG. 6. Those elements, portions or layers are labeled as the same or similar numerals, and will not be discussed in detail again. The difference between the present embodiment and the embodiment shown in FIG. 6 is that as shown in FIG. 7, the second optical layer 140 further includes a plurality of outer optical pillars 148 disposed around the optical ring structure 142, the optical poles 144 and 145. In particular, the outer optical pillars 148 are spaced apart from the optical ring structure 142, the optical poles 144 and 145. For example, the outer optical pillars 148 are located on each edge of the red pixel 110R and/or the blue pixel 110B. As a result, the light-coupling effect can be improved at the edges of the pixels, thereby improving the performance of the image sensing device 100E. It should be noted that the outer optical pillars 148 may be arranged offset from the edges of the red pixel 110R and/or the blue pixel 110B. However, the present disclosure is not limited thereto. In some embodiments, the distance between one optical pillar 144 and the nearest outer optical pillar 148 may be less than the distance between one optical pillar 145 and the nearest outer optical pillar 148. However, the present disclosure is not limited thereto.

FIG. 8 is a schematic plan view illustrating the image sensing device 100F in accordance with some embodiments of the present disclosure. It is noted that the image sensing device 100F in the present embodiment may include the same or similar elements, portions or layers as the image sensing device 100E shown in FIG. 7. Those elements, portions or layers are labeled as the same or similar numerals, and will not be discussed in detail again. The difference between the present embodiment and the embodiment shown in FIG. 7 is that as shown in FIG. 8, additional outer optical pillars 148 are disposed along the diagonal direction of the red pixel 110R and the blue pixel 110B, and may be separated from the remaining outer optical pillars 148. As a result, the light-coupling effect can be improved at corners of the pixels, thereby improving the performance of the image sensing device 100F.

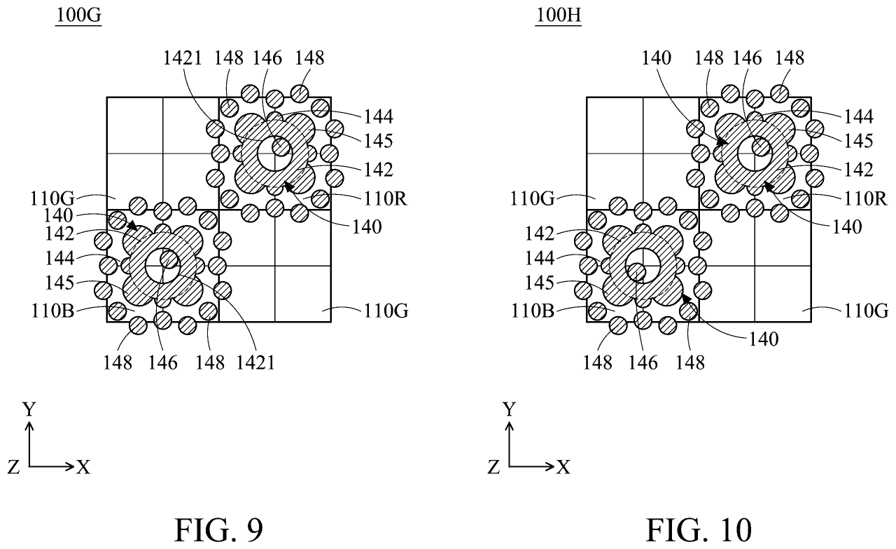

FIG. 9 is a schematic plan view illustrating the image sensing device 100G in accordance with some embodiments of the present disclosure. It is noted that the image sensing device 100G in the present embodiment may include the same or similar elements, portions or layers as the image sensing device 100F shown in FIG. 8. Those elements, portions or layers are labeled as the same or similar numerals, and will not be discussed in detail again. The difference between the present embodiment and the embodiment shown in FIG. 8 is that as shown in FIG. 9, the inner optical pillar 146 in each of the optical ring structure 142 is offset from the center of the optical ring structure 142. For example, the inner optical pillar 146 in the red pixel 110R is shifted towards the upper right corner of the red pixel 110R, and inner optical pillar 146 in the blue pixel 110B is also shifted towards the upper right corner of the blue pixel 110B. In some embodiments, the inner optical pillar 146 may be in contact with the inner edge 1421 of the optical ring structure 142. However, the present disclosure is not limited thereto. In some other embodiments, the inner optical pillar 146 may be spaced apart from the inner edge 1421 of the optical ring structure 142.

FIG. 10 is a schematic plan view illustrating the image sensing device 100H in accordance with some embodiments of the present disclosure. It is noted that the image sensing device 100H in the present embodiment may include the same or similar elements, portions or layers as the image sensing device 100G shown in FIG. 9. Those elements, portions or layers are labeled as the same or similar numerals, and will not be discussed in detail again. The difference between the present embodiment and the embodiment shown in FIG. 9 is that as shown in FIG. 10, the inner optical pillar 146 in the red pixel 110R is shifted towards the upper right corner of the red pixel 110R, and inner optical pillar 146 in the blue pixel 110B is shifted towards the lower left corner of the blue pixel 110B. It should be noted that any possible configuration with offset inner optical pillar 146 is included within the scope of the present disclosure.

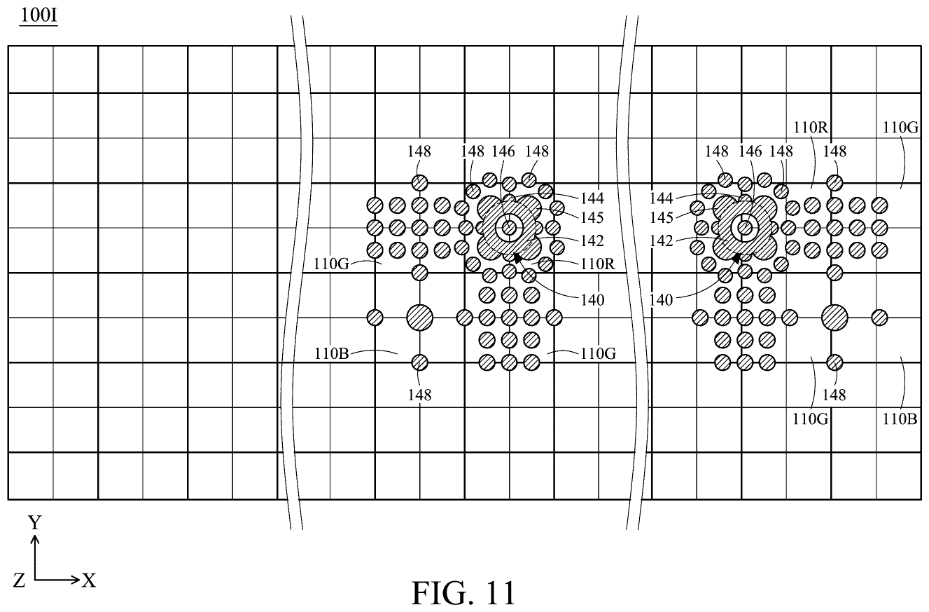

FIG. 11 is a schematic plan view illustrating the image sensing device 100I in accordance with some embodiments of the present disclosure. It is noted that the image sensing device 100I in the present embodiment may include the same or similar elements, portions or layers as the image sensing device 100F shown in FIG. 8. Those elements, portions or layers are labeled as the same or similar numerals, and will not be discussed in detail again. The difference between the present embodiment and the embodiment shown in FIG. 8 is that as shown in FIG. 11, the second optical layer 140 further includes additional outer optical pillars 148 over the green pixels 110G and the blue pixel 110B. In addition, the optical patterns (including the optical ring structure 142, the optical poles 144, 145, the inner optical pillar 146 and the outer optical pillars 148, etc.) in the edge of the image sensing device 100I are shifted toward the center of the image sensing device 100I. Accordingly, when the image sensing device 100I receives the incident light, the light-coupling effect may occur correspondingly across the image sensing device 100I, thereby improving the performance of the image sensing device 100I. In some embodiments, the inner optical pillar 146 in the edge pixels may also shift toward (that is, closer to) the inner edge of the optical ring structure 142.

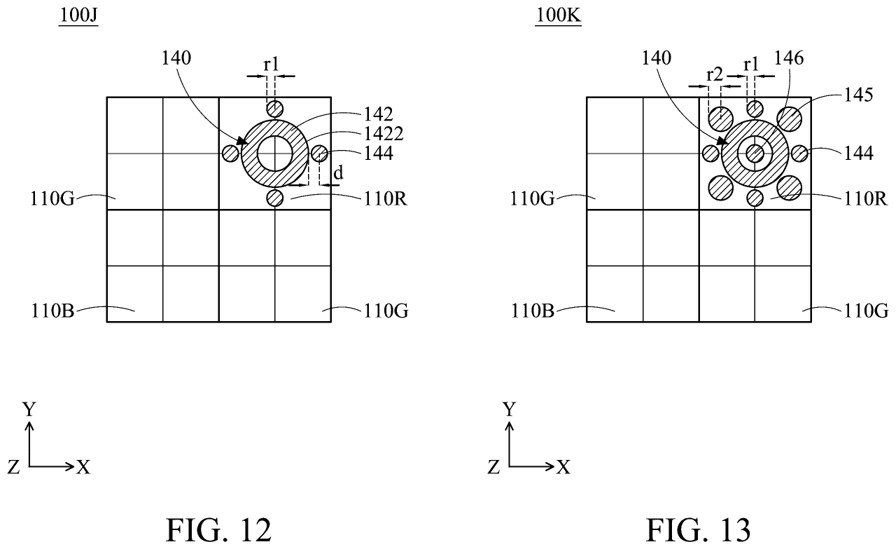

FIG. 12 is a schematic plan view illustrating the image sensing device 100J in accordance with some embodiments of the present disclosure. It is noted that the image sensing device 100J in the present embodiment may include the same or similar elements, portions or layers as the image sensing device 100 shown in FIG. 1. Those elements, portions or layers are labeled as the same or similar numerals, and will not be discussed in detail again. The difference between the present embodiment and the embodiment shown in FIG. 1 is that as shown in FIG. 12, the optical poles 144 are spaced apart from the outer edge 1422 of the optical ring structure 142 when viewed in the central axis 142C (for example, the Z axis) of the optical ring structure 142. The radius r1 of the optical poles 144 is less than the inner radius R1 of the optical ring structure 142. In some embodiments, the distance d between the center of one of the optical poles 144 and the outer edge 1422 of the optical ring structure 142 is less than half of the wavelength of visible light. For example, the distance d between the center of one of the optical poles 144 and the outer edge 1422 of the optical ring structure 142 is less than about 150 nm. Accordingly, the light-coupling effect may occur in the image sensing device 100J, and the size of the light spot can be reduced, thereby improving the performance of auto-focus of the image sensing device 100J.

FIG. 13 is a schematic plan view illustrating the image sensing device 100K in accordance with some embodiments of the present disclosure. It is noted that the image sensing device 100K in the present embodiment may include the same or similar elements, portions or layers as the image sensing device 100J shown in FIG. 12. Those elements, portions or layers are labeled as the same or similar numerals, and will not be discussed in detail again. The difference between the present embodiment and the embodiment shown in FIG. 12 is that as shown in FIG. 13, the second optical layer 140 includes four optical poles 144 and four optical poles 145 which have different sizes when viewed in the central axis 142C (for example, the Z axis) of the optical ring structure 142. In particular, the radius r1 of the optical poles 144 is less than the radius r2 of the optical poles 145, and the radii r1 and r2 are both less than the inner radius R1 of the optical ring structure 142. For example, the optical poles 145 may be arranged along the diagonal direction of the red pixel 110R, and the optical poles 144 may be arranged along the X axis and the Y axis. As a result, the light-coupling effect can be improved at corners of the pixels, thereby improving the performance of the image sensing device 100K. In addition, the second optical layer 140 further includes an inner optical pillar 146 located inside the inner edge 1421 of the optical ring structure 142. In particular, the inner optical pillar 146 may be aligned with the center of the optical ring structure 142. For example, the distance between the edge of the inner optical pillar 146 and the inner edge 1421 of the optical ring structure 142 is constant. As a result, the light-coupling effect can be improved at the center of the pixels, thereby improving the performance of the image sensing device 100K.

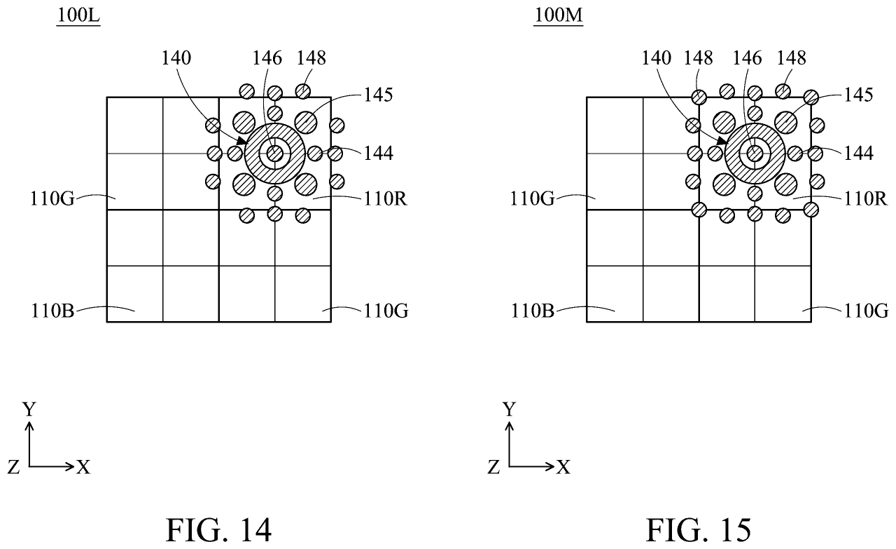

FIG. 14 is a schematic plan view illustrating the image sensing device 100L in accordance with some embodiments of the present disclosure. It is noted that the image sensing device 100L in the present embodiment may include the same or similar elements, portions or layers as the image sensing device 100K shown in FIG. 13. Those elements, portions or layers are labeled as the same or similar numerals, and will not be discussed in detail again. The difference between the present embodiment and the embodiment shown in FIG. 13 is that as shown in FIG. 14, the second optical layer 140 further includes a plurality of outer optical pillars 148 disposed around the optical ring structure 142, the optical poles 144 and 145. In particular, the outer optical pillars 148 are spaced apart from the optical ring structure 142, the optical poles 144 and 145. For example, the outer optical pillars 148 are located on each edge of the red pixel 110R. It should be noted that the outer optical pillars 148 may be arranged offset from the edges of the red pixel 110R. However, the present disclosure is not limited thereto. As a result, the light-coupling effect can be improved at the edges of the pixels, thereby improving the performance of the image sensing device 100L. In some embodiments, the distance between one optical pillar 144 and the nearest outer optical pillar 148 may be less than the distance between one optical pillar 145 and the nearest outer optical pillar 148. However, the present disclosure is not limited thereto.

FIG. 15 is a schematic plan view illustrating the image sensing device 100M in accordance with some embodiments of the present disclosure. It is noted that the image sensing device 100M in the present embodiment may include the same or similar elements, portions or layers as the image sensing device 100L shown in FIG. 14. Those elements, portions or layers are labeled as the same or similar numerals, and will not be discussed in detail again. The difference between the present embodiment and the embodiment shown in FIG. 14 is that as shown in FIG. 15, additional outer optical pillars 148 are disposed along the diagonal direction of the red pixel 110R, and may be separated from the remaining outer optical pillars 148. As a result, the light-coupling effect can be improved at corners of the pixels, thereby improving the performance of the image sensing device 100M.

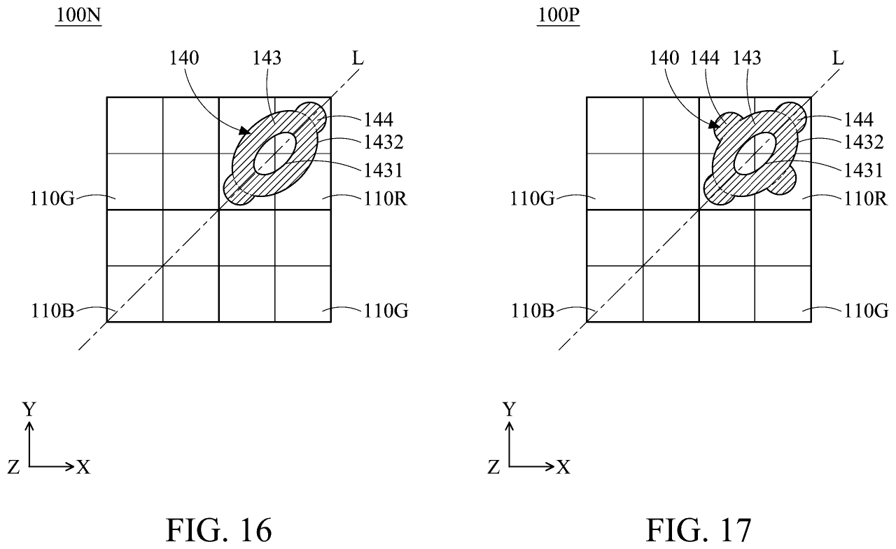

FIG. 16 is a schematic plan view illustrating the image sensing device 100N in accordance with some embodiments of the present disclosure. It is noted that the image sensing device 100N in the present embodiment may include the same or similar elements, portions or layers as the image sensing device 100 shown in FIG. 1. Those elements, portions or layers are labeled as the same or similar numerals, and will not be discussed in detail again. The difference between the present embodiment and the embodiment shown in FIG. 1 is that as shown in FIG. 16, the second optical layer 140 include an optical ring structure 143 which is elliptical when viewed in the central axis 142C (for example, the Z axis) of the optical ring structure 142. In particular, the macro axis L of the optical ring structure 143 is substantially parallel to the diagonal direction of the red pixel 110R. Furthermore, two optical poles 144 are disposed around the optical ring structure 143. In particular, the optical poles 144 may be arranged along the macro axis of the optical ring structure 143 (that is, the diagonal direction of the red pixel 110R), and the optical poles 144 around the optical ring structure 143 may be opposite to each other.

FIG. 17 is a schematic plan view illustrating the image sensing device 100P in accordance with some embodiments of the present disclosure. It is noted that the image sensing device 100P in the present embodiment may include the same or similar elements, portions or layers as the image sensing device 100N shown in FIG. 16. Those elements, portions or layers are labeled as the same or similar numerals, and will not be discussed in detail again. The difference between the present embodiment and the embodiment shown in FIG. 16 is that as shown in FIG. 17, additional two optical poles 144 may be arranged along the mi-nor axis of the optical ring structure 143 (that is, the diagonal direction of the red pixel 110R). In particular, an angle of 90 degrees is formed between adjacent optical poles 144. As a result, the light-coupling effect of the incident light would be uniform across the image sensing device 100P, thereby improving the performance of the image sensing device 100P.

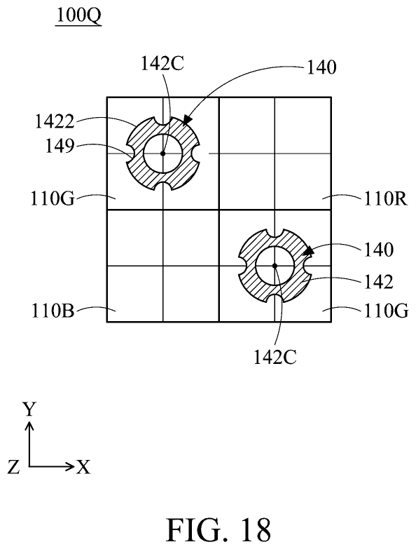

FIG. 18 is a schematic plan view illustrating the image sensing device 100Q in accordance with some embodiments of the present disclosure. It is noted that the image sensing device 100Q in the present embodiment may include the same or similar elements, portions or layers as the image sensing device 100A shown in FIG. 3. Those elements, portions or layers are labeled as the same or similar numerals, and will not be discussed in detail again. The difference between the present embodiment and the embodiment shown in FIG. 3 is that as shown in FIG. 18, the second optical layer 140 includes a plurality of optical ring structures 142, each of which includes a plurality of curved surfaces 149. The curved surfaces 149 are recessed from the outer edge 1422 of each of the optical ring structures 142, and extend toward the central axis 142C. In some embodiments, the curved surfaces 149 are arranged around the outer edge 1422 of the optical ring structure 142 at regular intervals when viewed in the central axis 142C of the optical ring structure 142. As a result, the light-coupling effect can be improved at corners of the pixels, thereby improving the performance of the image sensing device 100Q.

It should be noted that various embodiments are provided above, and those skilled in the art should be able to realize that single image sensing device may include one or more of these embodiments based on the present disclosure.

As set forth above, the embodiments of the present disclosure provide an image sensing device including a plurality of optical poles around the outer edge of the optical ring structure over the sensor substrate. As a result, the size of the incident light spot can be reduced, thereby improving the performance of auto-focus of the image sensing device. In addition, inner optical pillar and/or outer optical poles can be selectively disposed to further improve the performance of the image sensing device.

While the embodiments and the advantages of the present disclosure have been described above, it should be understood that those skilled in the art may make various changes, substitutions, and alterations to the present disclosure without departing from the spirit and scope of the present disclosure. It should be noted that different embodiments in the present disclosure may be arbitrarily combined as other embodiments as long as the combination conforms to the spirit of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. An image sensing device, comprising:
a sensor substrate having a normal direction;
a color filter layer over the sensor substrate;
a first optical layer formed over the color filter layer; and
a second optical layer formed over the first optical layer, wherein the second optical layer comprises:
an optical ring structure having an inner edge and an outer edge around a central axis of the optical ring structure, wherein the central axis of the optical ring structure is substantially parallel to the normal direction of the sensor substrate; and
a plurality of optical poles, wherein when viewed in the central axis of the optical ring structure, the optical poles are located around the outer edge of the optical ring structure, and a radius of the optical poles is less than an inner radius of the optical ring structure, and the inner radius of the optical ring structure is defined from the central axis to the inner edge of the optical ring structure in a direction perpendicular to the central axis of the optical ring structure.

2. The image sensing device as claimed in claim 1, wherein the second optical layer comprises a plurality of layers of the optical ring structure, and a spacing between adjacent layers of the optical ring structure is from about 10 nm to about 200 nm.

3. The image sensing device as claimed in claim 2, wherein the layers of the optical ring structure comprise different patterns.

4. The image sensing device as claimed in claim 1, wherein the inner radius of the optical ring structure is in a range from about 25 nm to about 350 nm when viewed in the central axis of the optical ring structure.

5. The image sensing device as claimed in claim 1, wherein a distance between a center of one of the optical poles and the outer edge of the optical ring structure is less than about 150 nm.

6. The image sensing device as claimed in claim 1, wherein an outer radius of the optical ring structure is in a range from about 100 nm to about 1000 nm when viewed in the central axis of the optical ring structure, and the outer radius of the optical ring structure is defined from the central axis to the outer edge of the optical ring structure in the direction perpendicular to the central axis of the optical ring structure.

7. The image sensing device as claimed in claim 1, wherein the optical poles are integrated with the outer edge of the optical ring structure, and a periphery of one of the optical poles is an arc connected to the outer edge of the optical ring structure.

8. The image sensing device as claimed in claim 1, wherein the optical poles have different sizes when viewed in the central axis of the optical ring structure.

9. The image sensing device as claimed in claim 1, wherein the second optical layer further comprises an inner optical pillar disposed inside the inner edge of the optical ring structure, and a radius of the inner optical pillar is less than the inner radius of the optical ring structure when viewed in the central axis of the optical ring structure.

10. The image sensing device as claimed in claim 9, wherein the inner optical pillar is located at the central axis of the optical ring structure.

11. The image sensing device as claimed in claim 9, wherein the inner optical pillar is offset from the central axis of the optical ring structure.

12. The image sensing device as claimed in claim 11, wherein the inner optical pillar is in contact with the inner edge of the optical ring structure.

13. The image sensing device as claimed in claim 1, wherein the second optical layer further comprises a plurality of outer optical pillars disposed around the optical ring structure and the optical poles.

14. The image sensing device as claimed in claim 1, wherein the sensor substrate defines a plurality of pixels, the optical ring structure overlaps one of the pixels in a normal direction of the sensor substrate, and the center axis of the optical ring structure is offset from a center of the one of the pixels.

15. The image sensing device as claimed in claim 1, wherein the second optical layer further comprises an additional optical ring structure over the optical ring structure.

16. The image sensing device as claimed in claim 1, wherein the optical poles are arranged along a diagonal direction of the sensor substrate when viewed in the central axis of the optical ring structure.

17. The image sensing device as claimed in claim 1, wherein a number of the optical poles around the outer edge of the optical ring structure is 2, 4, or 8, and the optical poles are arranged around the outer edge of the optical ring structure at regular intervals when viewed in the central axis of the optical ring structure.

18. The image sensing device as claimed in claim 1, wherein the optical ring structure is circular or elliptical when viewed in the central axis of the optical ring structure.

19. The image sensing device as claimed in claim 1, wherein the optical ring structure and the optical poles are made of a dielectric material, and a refraction index of the optical ring structure and the optical poles is in a range from 1.7 to 2.3.

20. The image sensing device as claimed in claim 1, further comprising an anti-reflection layer formed over the second optical layer.
